(19) United States
(12) Patent Application Publication
(10) Pub. No.: US 2007/0051387 A1
(43) Pub. Date: Mar. 8, 2007

(54) Method of cleaning plasma applicator in situ and plasma applicator employing the same

(76) Inventors: Wan-goo Hwang, Yongin-si (KR); No-hyun Huh, Yongin-si (KR); Il-kyoung Kim, Seoul (KR); Jeong-soo Suh, Seoul (KR); Ki-young Yun, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/510,757

(22) Filed: Aug. 28, 2006

(30) Foreign Application Priority Data
Sep. 2, 2005 (KR) 10-2005-0081849

(51) Int. Cl. B08B 6/00; C23C 16/00

(52) U.S. Cl. 134/1.1; 118/723 MW

(57) ABSTRACT

A method of cleaning a plasma generating area of a plasma applicator in situ is disclosed and comprises; supplying a by-product cleaning gas to the plasma generating area, and generating a plasma from the by-product cleaning gas in the plasma generating area.

### BACKGROUND OF THE INVENTION

1. Field of the Invention

Embodiments of the invention relate to a semiconductor manufacturing system. More particularly, embodiments of the invention relate to a plasma applicator, a plasma native oxide cleaning apparatus, and a related method of cleaning same.

This application claims the benefit of Korean Patent Application No. 10-2005-0081849, filed on Sep. 2, 2005, the subject matter of which is hereby incorporated by reference in its entirety.

2. Description of the Related Art

Conventionally, the tough native oxide layer that forms on a silicon wafer during the fabrication of semiconductor devices is removed using a wet cleaning method characterized by the presence of a chemical solution containing dilute fluoric acid (HF). However, as the size of the fabricated regions and elements from the semiconductor devices has shrunk over the years with ever increasing densities, the conventional wet cleaning method has confronted limitations in its use. As a result, a dry cleaning method has been proposed as an alternative. Of note, the proposed dry cleaning method makes use of a remote plasma cleaning apparatus.

The remote plasma cleaning apparatus diffuses reactive radicals throughout the reaction chamber and otherwise mixes dilution gases. (The reactive radicals are actually generated by a plasma applicator remotely located from the reaction chamber). Through the use of the remote plasma cleaning apparatus, wafers being processed and other components within the reaction chamber may be more readily cleaned. That is, the related cleaning method increases fluidity of the gases passing through the reaction chamber by generating a mixture of gases and radicals. The cleaning method also concurrently decreases the etch rate of a material within the reaction chamber that would otherwise be caused by unmixed reactive radicals.

FIG. 1 is a diagram generally illustrating a conventional remote plasma cleaning apparatus adapted for use with a remote plasma cleaning method.

The remote plasma cleaning apparatus includes a reaction chamber 20, a plasma applicator 10 and upper and lower reaction gas lines 31 and 32. Reaction chamber 20 includes a main chamber 22, a load lock chamber 26 and a wafer releasing opening 24. Load lock chamber 26 includes a wafer charge boat 27 and provides a wafer to main chamber 22. The cleaned wafer is released from reaction chamber 20 through wafer releasing opening 24.

Plasma applicator 10 includes a plasma generating area 12, a microwave supplier 14 and a microwave oscillator 16. Upper and lower reaction gas lines 31 and 32 are adapted to supply reaction gas and are connected to plasma applicator 10. For instance, a reaction gas including nitrogen (N₂) gas and hydrogen (H₂) gas is supplied through upper reaction gas line 31 to remove a native oxide layer. Argon (Ar) gas is supplied through lower reaction gas line 32 to stabilize the formed plasma.

As for a cleaning process, the mixture gas of N₂ gas and H₂ gas supplied through upper reaction gas line 31 is transformed into a plasma state by plasma applicator 10. The reaction gas is thus activated and formed into a plasma containing radicals and/or ions. The activation reaction gas then activates nitrogen trifluoride (NF₃) gas being directly supplied to main chamber 22. The activated nitrogen trifluoride (NF₃) gas reacts with any native oxide present on the surface of a target wafer to form a reactive layer. The reactive layer may then be removed by vaporizing it in a subsequently applied annealing process.

The nitrogen-based reaction gas produces by-products “A” during the activation process. By-products “A” are deposited, for example, on the inner walls of plasma generating area 12. In many conventional forms, the inner walls of plasma generating area 12 are formed from quartz. The activated reaction gas (particularly those produced from (N₂) or ammonia (NH₃)) reacts with the quartz to form a trisilicon tetranitirde (Si₃N₄) layer. (A silicon oxide (SiO₂) layer may also be similarly formed within the plasma generating area 12). During a continuous cleaning process routinely applied to the remote plasma cleaning apparatus, the developed trisilicon tetranitride (Si₃N₄) layer generally flakes off the inner walls of plasma generating area 12 to form particles. These particles may be carried into reaction chamber 20 and contaminating the wafer being processed.

FIG. 2 illustrates images of wafers contaminated with Si₃N₄-containing particles. The wafer surface is contaminated by these particles in a very consistent pattern (e.g., one shaped like a gingko leave). This pattern of Si₃N₄ - containing particles occurs because the activated reaction gas (and with it the Si₃N₄-containing particles) is supplied to reaction chamber 20 in a single fixed direction, while the wafer being processed in rotated during the cleaning process.

As a result of this contamination, periodic replacement of the conventional plasma applicator is necessary. This periodic replacement is quite expensive and is responsible for cleaning system down time.

### SUMMARY OF THE INVENTION

In contrast, embodiments of the invention provide an “in situ” cleaning method, adapted to remove Si₃N₄-containing particles generated within a plasma applicator. Embodiments of the invention also provide a plasma applicator and related method of operation.

Thus, in one embodiment, the invention provides a method of cleaning a plasma generating area of a plasma applicator in situ, the method comprising; supplying a by-product cleaning gas to the plasma generating area, and generating a plasma from the by-product cleaning gas in the plasma generating area.

In another embodiment, the invention provides a plasma applicator, comprising; a plasma generating area adapted to generate plasma from a reaction gas and connected between a reaction chamber and at least one first gas line supplying the reaction gas and a second gas line supplying a by-product cleaning gas, and a microwave supplier adapted to apply microwave energy to the plasma generating area.

### BRIEF DESCRIPTION OF THE DRAWINGS

FIG. 1 is a cross-sectional view illustrating a plasma applicator and a reaction chamber of a conventional remote plasma cleaning apparatus;

FIG. 2 illustrates images of contaminated wafers caused by the use of a conventional plasma applicator;

FIG. 3 is a cross-sectional view illustrating a plasma applicator employing a by-product reaction gas line according to a first embodiment of the present invention;

FIG. 4 is a cross-sectional view illustrating a plasma applicator employing a by-product reaction gas line according to a second embodiment of the present invention;

FIG. 5 is a flowchart illustrating a method of cleaning a plasma applicator in situ according to a third embodiment of the present invention; and

FIG. 6 is a graph illustrating decrease of defective wafers after using any one of the plasma applicators according to the first to third embodiments of the present invention.

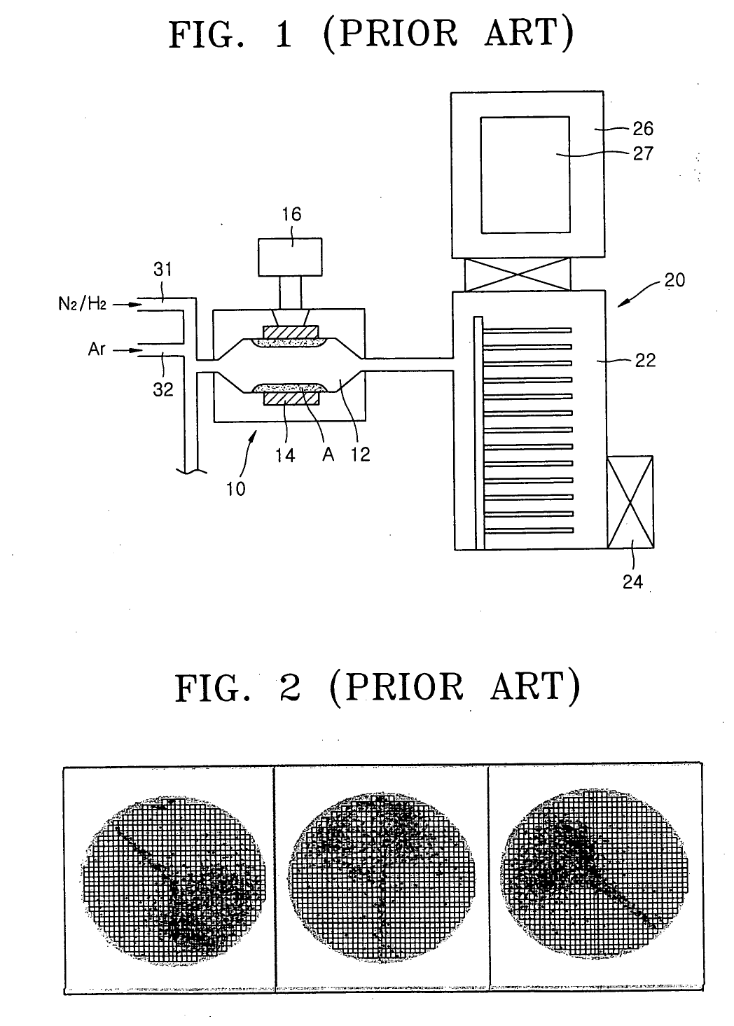

### DESCRIPTION OF EXEMPLARY EMBODIMENTS

Embodiments of the invention will now be described with reference to the accompanying drawings. The invention may, however, be embodied in many different forms and should not be construed as being limited to only the embodiments set forth herein. Rather, the illustrated embodiments are provided as teaching examples.

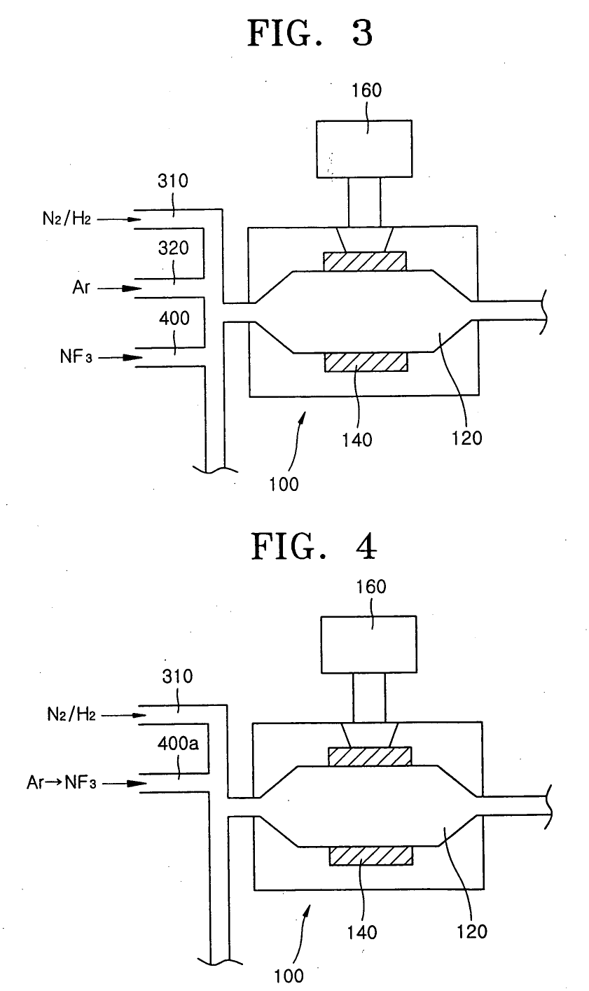

FIG. 3 is a cross-sectional view illustrating a plasma applicator employing a by-product cleaning gas line and reaction gas lines according to one embodiment of the invention. The term “reaction gas lines” referred to one or more gas lines adapted to introduce one or more gases into the plasma generating chamber.

The plasma applicator 100 illustrated in FIG. 3 generally comprises a plasma generating area 120, a microwave supplier 140 and a microwave oscillator 160. Plasma generating area 120 is connected between the reaction gas lines 310 and 320 and a reaction chamber. Unlike the conventional plasma applicator, a by-product cleaning gas line 400 adapted to introduce one or more gases adapted to clean plasma applicator 100 is additionally connected to plasma applicator 100.

In one embodiment, a nitrogen-containing gas is introduced as a reaction gas though at least one of reaction gas lines 310 and 320. This nitrogen-containing reaction gas may comprise one or more gases such as N₂, N₂/H₂, NH₃, and NH3/N₂. Plasma generating area 120 is substantially formed from quartz. When activated, the nitrogen-containing reaction gas reacts with quartz, and generally causes the development of one or more by-product materials, such as a Si₃N₄ layer or a SiO₂ layer, on the inner walls of plasma generating area 120.

Therefore, a by-product cleaning gas is necessary to remove any accumulated by-product materials. Thus, by-product cleaning gas line 400 is additionally installed to supply a by-product cleaning gas to plasma generating area 120. In one example, illustrated in FIG. 3, the by-product cleaning gas is NF₃ gas, which is effective to cleaning Si₃N₄. However, the by-product cleaning gas might also comprise a fluorine-based gas such as F₂. Argon (Ar) gas may be supplied through one of the reaction gas lines 310 and 320 to stabilize plasma.

The by-product cleaning gas introduced into plasma generating area 120 is transformed into a plasma state by the applied microwave energy. This plasma contains fluorine radicals which are introduced into plasma generating area 120. The fluorine radicals decompose the accumulated by-product materials deposited on the inner walls of plasma generating area 120. In this decomposed gaseous state, the by-product materials are easily removed. In one specific embodiment, the by-product removal process was performed for approximately 20 seconds at a pressure of approximately 3.7 torr with an applied microwave power of approximately 1,200 W. NF₃ was used as the by-product cleaning gas and supplied at a flow rate of approximately 500 sccm.

FIG. 4 is a cross-sectional view illustrating a plasma applicator employing one connected by-product cleaning gas line and one connected reaction gas line according to another embodiment of the invention.

Plasma applicator 100 generally comprises the same elements as described above with reference to FIG. 3. However, different from the former embodiment, one reaction gas line 310 and one by-product cleaning line 400A are used. With this arrangement, Ar gas (a stabilizing component of the reaction gas) is introduced through the same line as the by-product cleaning gas (e.g., NF₃). As this arrangement of gas line resembles the conventional apparatus the installation cost associated with adding a separate by-product cleaning gas line is avoided.

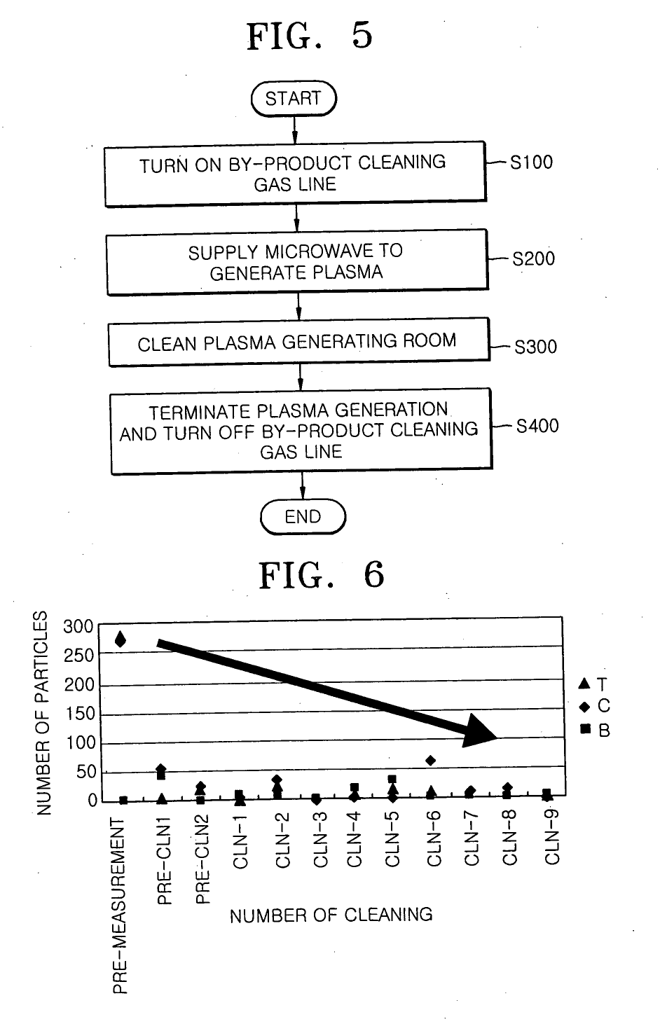

FIG. 5 is a flowchart illustrating a method of cleaning a plasma applicator according to an embodiment of the present invention. The exemplary apparatus shown in either FIGS. 3 or 4 may be further referenced as part of the method description.

In operation, a by-product cleaning gas is introduced to the plasma generating area 120 through a second line as a by-product cleaning gas supply is turned ON (S100). Here, the by-product cleaning gas is assumed to be NF₃ gas. With the by-product cleaning gas introduced, microwave oscillator 160 is activated to supply microwave energy through microwave supplier 140 into plasma generating area 120. This application produces a by-product cleaning gas plasma (S200). The by-product cleaning gas plasma is activated and reacts with any accumulated by-product material to vaporize and remove them from plasma generating area 120 (S300). After completion of the cleaning process, plasma generation is terminated, and the supply of by-product cleaning gas through the second line is turned OFF (S400). Before and after the supply of by-product cleaning gas is turned ON, Ar gas may be supplied to stabilize the plasma.

FIG. 6 is a graph illustrating a decrease in defective wafers after plasma generating area 120 was cleaned using a by-product cleaning gas (e.g., NF₃ gas) according to an embodiment of the invention. In a conventional cleaning system, more than 300 contamination particles were discovered on a test wafer's surface. However, following application of a cleaning process consistent with the foregoing, the number of contamination particles on a test wafer's surface decreased to approximately 50 or less. Herein, the horizontal axis and the vertical axis represent the number of cleaning and the number of particles, respectively. Reference denotations ‘T’, ‘C’ and ‘B’ are markers indicating an allocation of loaded wafers within reaction chamber 20. For instance, ‘T’ represents a wafer loaded at a top zone; ‘C’ represents a wafer loaded at a center zone; and ‘B’ represents a wafer loaded at a bottom zone.

Therefore, before the cleaning, wafers at the ‘T’ and ‘C’ sites were particularly contaminated with Si₃N₄ particles. After application of a cleaning process consistent with embodiments of the invention, most of the test wafers sampled had less than approximately 50 contamination particles. Herein, ‘CLN’ expresses the number of performed cleaning processes, and ‘Pre-Measurement’ and ‘Pre-CLN’ mean before the cleaning and the cleaning between ‘Pre-Measurement’ and ‘CLN’ with reinforcing the cleaning condition, respectively. The reinforcement of the cleaning condition means that the execution time of the cleaning by the NF₃ gas is longer than a typical execution time of the cleaning, which runs for approximately 20 seconds. In one embodiment, execution time for the cleaning process was approximately 5 minutes. The reinforcement of the cleaning condition is necessary because lots of by-products may exist within the plasma generating area when the cleaning is initially implemented. The cleaning proceeds as the following: after the first execution of the cleaning by the NF₃ gas, the wafers within the reaction chamber are cleaned; and after the second execution of the cleaning by the NF₃ gas, the wafers are cleaned again.

According to the exemplary embodiments of the invention, by-products, which can be generated at the plasma applicator of a PNC system, can be cleaned in situ by connecting a by-product cleaning gas line with a plasma generation area of a plasma applicator. Since the by-products can be cleaned using plasma obtained by supplying a by-product cleaning gas such as NF₃ gas, a conventional approach of disassembling and replacing the plasma applicator to remove the by-products is not necessary.

Also, installation of an additional gas line is not required since the conventionally employed reaction gas lines can be used as a gas line for supplying the by-product cleaning gas.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of cleaning a plasma generating area of a plasma applicator in situ, the method comprising:
supplying a by-product cleaning gas to the plasma generating area; and, generating a plasma from the by-product cleaning gas in the plasma generating area.

2. The method of claim 1, wherein the plasma generating area comprises quartz inner walls and is adapted to activate a reaction gas comprising at least gas selected from a group consisting of N₂, N₂/H₂, NH₃, and NH₃/N₂.

3. The method of claim 2, wherein a Si₃N₄ by-product layer or a SiO₂ by-product layer results from activated on the reaction gas.

4. The method of claim 1, wherein the by-product cleaning gas comprises a fluorine gas.

5. The method of claim 4, wherein the by-product cleaning gas comprises NF₃ gas or F₂ gas.

6. The method of claim 1, wherein the by-product cleaning gas and the reaction gas are supplied through separate lines.

7. The method of claim 1, wherein the in situ cleaning is performed for approximately 20 seconds at a pressure of approximately 3.7 torr using a microwave power of approximately 1,200 W and a by-product cleaning gas flow rate of approximately 500 sccm.

8. The method of claim 1, wherein the in situ cleaning is carried out prior to cleaning wafers.

9. The method of claim 1, wherein upon initial in situ cleaning, the in situ cleaning is performed for more than approximately 1 minute.

10. The method of claim 2, wherein the reaction gas further comprises Ar gas.

11. The method of claim 10, wherein the Ar gas is introduced in the plasma generating area through the same line as the by-product cleaning gas.

12. A plasma applicator, comprising:
a plasma generating area adapted to generate plasma from a reaction gas and connected-between a reaction chamber and at least one first gas line supplying the reaction gas and a second gas line supplying a by-product cleaning gas; and
a microwave supplier adapted to apply microwave energy to the plasma generating area.

13. The plasma applicator of claim 12, wherein the plasma generating area comprises quartz inner walls, and the reaction gas comprises at least one gas selected from a group consisting of N₂, N₂/H₂, NH₃, and NH₃/N₂.

14. The plasma applicator of claim 12, wherein the by-product cleaning gas comprises a fluorine gas.

15. The plasma applicator of claim 14, wherein the fluorine gas is NF₃ gas or F₂ gas.

16. The plasma applicator of 13, wherein a Si₃N₄ by-product layer or a SiO₂ by-product layer is generated on the inner walls of the plasma generating area upon application of the microwave energy to the reaction gas.

17. The plasma applicator of claim 13, wherein the at least one first gas line comprises one line introducing the reaction gas into the plasma generating area and another line introducing Ar gas into the plasma generating area.

18. The plasma applicator of claim 13, wherein the at least one first gas line comprises one line introducing the reaction gas into the plasma generating area and the second gas line is adapted to introduce the by-product cleaning gas and Ar gas into the plasma generating area.

19. The method of claim 18, wherein the by-product cleaning gas comprises a fluorine gas.

20. The method of claim 19, wherein the by-product cleaning gas comprises NF₃ gas or F₂ gas.
